(19) United States
(12) Patent Application Publication
(10) Pub. No.: US 2015/0137072 A1
(43) Pub. Date: May 21, 2015

(54) MASK FOR FORMING SEMICONDUCTOR LAYER, SEMICONDUCTOR DEVICE, AND METHOD OF FABRICATING THE SAME

(71) Applicant: GWANGJU INSTITUTE OF SCIENCE AND TECHNOLOGY, Gwangju (KR)

(72) Inventors: Dong-Seon LEE, Gwangju (KR); Dongju SEO, Gwangju (KR); Junyoub LEE, Gwangju (KR); Dukjo KONG, Gwangju (KR); Chang Mo KANG, Gwangju (KR)

(21) Appl. No.: 14/541,675

(22) Filed: Nov. 14, 2014

(30) Foreign Application Priority Data
Nov. 19, 2013 (KR) 10-2013-0140581

(51) Int. Cl. H01L 33/06; H01L 33/32; H01L 33/00

(52) U.S. Cl. CPC H01L 33/06; H01L 33/0025; H01L 33/0075; H01L 33/32; H01L 33/0066; H01L 33/0079
USPC 257/14; 438/478

(57) ABSTRACT

A mask for forming a semiconductor layer and a semiconductor device manufactured using the same. The mask for forming a semiconductor layer includes oblique openings. Since a semiconductor layer is formed through one or more openings, it is possible to suppress generation of threading dislocation in a vertical direction from a growth surface of a heterogeneous substrate. The oblique openings are formed by stacking a growth blocking layer on the substrate, followed by dry etching the growth blocking layer, with the substrate disposed in a tilted state.

### CROSS REFERENCE TO RELATED APPLICATION

This application claims the benefit of Korean Patent Application No. 10-2013-0140581, filed on Nov. 19, 2013, entitled “MASK FOR FORMING SEMICONDUCTOR LAYER, SEMICONDUCTOR DEVICE, AND METHOD OF FABRICATING THE SAME”, which is hereby incorporated by reference in its entirety into this application.

### BACKGROUND

1. Technical Field

The present invention relates to a semiconductor device, and more particularly, to a mask for forming a semiconductor layer which can reduce dislocation due to lattice mismatch when growing a semiconductor layer on a heterogeneous substrate, a semiconductor device, and a method of fabricating the same.

2. Description of the Related Art

Semiconductor devices such as LEDs, solar cells, and the like include semiconductor layers such as GaN and InGaN grown on a substrate. Since such semiconductor layers are generally grown on a heterogeneous substrate such as a sapphire substrate, a silicon substrate, and the like, dislocation is produced due to lattice mismatch (see [a] of FIG. 1). Such dislocation can cause a serious problem in implementation of a high density/high performance semiconductor device.

In order to solve this problem, as illustrated in [b] and [c] of FIG. 1, PSS (Patterned Sapphire Substrate), ELOG (Epitaxial Lateral Overgrowth), and the like are utilized. However, these methods cannot sufficiently reduce threading dislocation which is generated in a vertical direction and provides a serious influence on device performance.

Therefore, there is a need for solutions capable of drastically reducing threading dislocation to obtain a high density/high performance semiconductor device.

### BRIEF SUMMARY

It is an aspect of the present invention to provide a mask for forming a semiconductor layer which can drastically reduce threading dislocation upon growth of a semiconductor layer on a heterogeneous substrate.

It is another aspect of the present invention to provide a method of fabricating the mask for forming a semiconductor layer as set forth above.

It is a further aspect of the present invention to provide a semiconductor device manufactured using the mask for forming a semiconductor layer as set forth above.

It is yet another aspect of the present invention to provide a method of fabricating a semiconductor device using the mask for forming a semiconductor layer as set forth above.

In accordance with one aspect of the present invention, a mask for forming a semiconductor layer includes: a blocking portion formed to a predetermined thickness on a growth surface of a substrate to block growth of a semiconductor layer; and at least one opening formed in the blocking portion to expose the growth surface of the substrate therethrough, wherein the at least one opening is oblique with respect to the growth surface of the substrate.

The blocking portion may be a SiO₂ layer stacked on the growth surface of the substrate.

In accordance with another aspect of the present invention, a method of fabricating a mask for forming a semiconductor layer includes; forming a growth blocking layer having a predetermined thickness on a substrate; and forming at least one opening exposing an upper surface of the substrate by partially removing the growth blocking layer, wherein forming at least one opening comprises dry etching the growth blocking layer with the substrate disposed in a tilted state such that the at least one opening is obliquely formed with respect to the upper surface of the substrate.

The growth blocking layer may be formed of SiO₂.

In accordance with a further aspect of the present invention, a semiconductor device includes: a first semiconductor layer formed on a substrate; and an upper structure layer formed on the first semiconductor layer, wherein at least the first semiconductor layer is partially or entirely oblique with respect to an upper surface of the substrate.

The upper structure layer may include an MQW layer and a second semiconductor layer.

The first semiconductor layer may be masked by a growth mask formed on the to upper surface of the substrate and having at least one opening exposing the upper surface of the substrate, while being grown in the opening.

The first semiconductor layer may be formed to cover an upper portion of the growth mask and enclose the growth mask.

The MQW layer may be formed to surround an upper surface and side surfaces of the first semiconductor layer, and the second semiconductor layer may be formed to surround an upper surface and side surfaces of the MQW layer.

In accordance with yet another aspect of the present invention, a method of fabricating a semiconductor device includes: (a) forming a growth mask including at least one opening oblique with respect to an upper surface of a substrate and formed to expose the upper surface of the substrate on the substrate therethrough; and (b) forming a first semiconductor layer within the at least one opening.

Step (a) may include: (a1) forming a growth blocking layer having a predetermined thickness on the substrate; (a2) forming an etching mask on an upper surface of the growth blocking layer; and (a3) tilting the substrate and dry etching the growth blocking layer to expose the upper surface of the substrate, with the growth blocking layer masked by the etching mask.

Step (b) may include growing the first semiconductor layer on the upper surface of the substrate exposed through the at least one opening.

The method may further include forming an upper structure layer including a second semiconductor layer on the first semiconductor layer within the at least one opening.

Alternatively, the method may further include removing the growth mask; and forming an upper structure layer including a second semiconductor layer on an upper surface and side surfaces of the first semiconductor layer.

Alternatively, the method may further include growing the first semiconductor layer beyond the openings to cover an upper portion of the growth mask.

Alternatively, the method may further include: selectively removing the growth mask; and removing a portion of the first semiconductor layer located within the at least one opening to separate the first semiconductor layer from the substrate.

According to the present invention, a mask for forming a semiconductor layer which has oblique openings to provide a space for growth of the semiconductor layer, and a semiconductor device manufactured using the same are provided. Such a mask for forming a semiconductor layer having the oblique openings can minimize threading dislocation in a grown semiconductor layer. Thus, high performance/high quality semiconductor devices including a semiconductor layer formed using the mask can be manufactured. Further, the mask for forming a semiconductor layer according to the invention allows production of various semiconductor devices.

### BRIEF DESCRIPTION OF THE DRAWINGS

The above and other aspects, features, and advantages of the present invention will become apparent from the detailed description of the following embodiments in conjunction with the accompanying drawings, wherein;

FIG. 1 shows side views illustrating a conventional method of growing a semiconductor layer on a substrate;

FIGS. 2a to 2d are side views of a mask for forming a semiconductor layer according to the present invention, and a method of fabricating the same;

FIG. 3 is a view showing examples in which a semiconductor layer is grown on a substrate using the mask for forming a semiconductor layer according to the present invention;

FIG. 4 is a view showing one example of a semiconductor device manufactured using the mask for forming a semiconductor layer according to the present invention;

FIG. 5 is a view showing another example of a semiconductor device manufactured using the mask for forming a semiconductor layer according to the present invention;

FIG. 6 is a view showing a further example of a semiconductor device manufactured using the mask for forming a semiconductor layer according to the present invention;

FIG. 7 is a view illustrating another example of a method of fabricating a semiconductor device using the mask for forming a semiconductor layer according to the present invention; and

FIG. 8 is a scanning electron microscope image of the mask for forming a semiconductor layer according to the present invention.

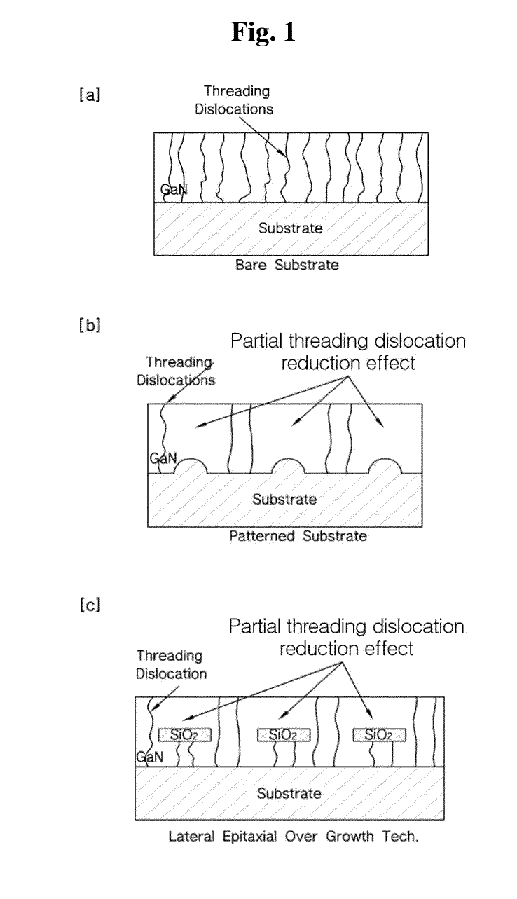

### DETAILED DESCRIPTION

Hereinafter, embodiments of the present invention will be described in detail with reference to the accompanying drawings. Further, in describing the present invention, a detailed description of related known functions or configurations will be omitted so as not to obscure the subject of the present invention.

According to the present invention, a growth mask having at least one oblique opening is formed by stacking a layer for a growth mask (growth blocking layer), for example, a SiO₂ layer, on a sapphire substrate or other heterogeneous substrates, followed by dry etching the growth blocking layer, with the substrate disposed in a tilted state. Growth of a semiconductor layer on a growth surface of the substrate exposed through the oblique opening can induce lateral growth, thereby minimizing density of threading dislocation. Further, various methods of manufacturing a semiconductor device using the growth mask according to the present invention are provided. By way of example, a semiconductor layer grown within the opening may be grown to merge into an upper portion of the growth mask, thereby forming a high quality template. Alternatively, a semiconductor layer grown within the respective openings may be grown in a stripe or rod shape to the extent that the semiconductor layer does not merge with each other. The rest of an upper structure for a semiconductor device may be regrown on such a stripe or rod shaped semiconductor layer.

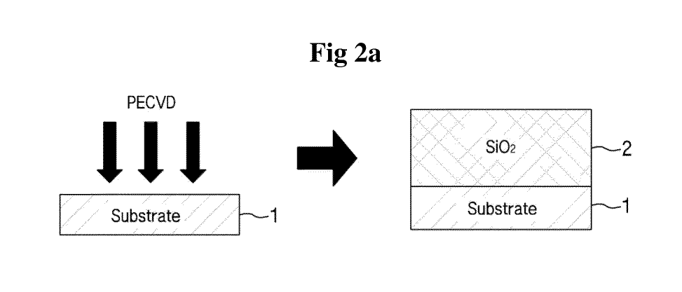

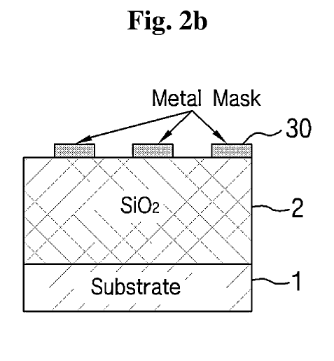

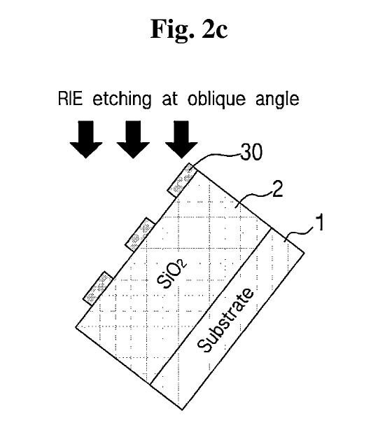

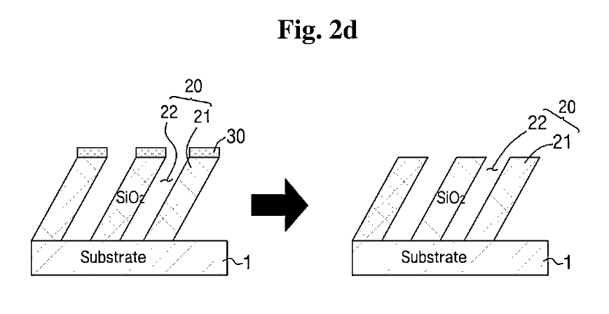

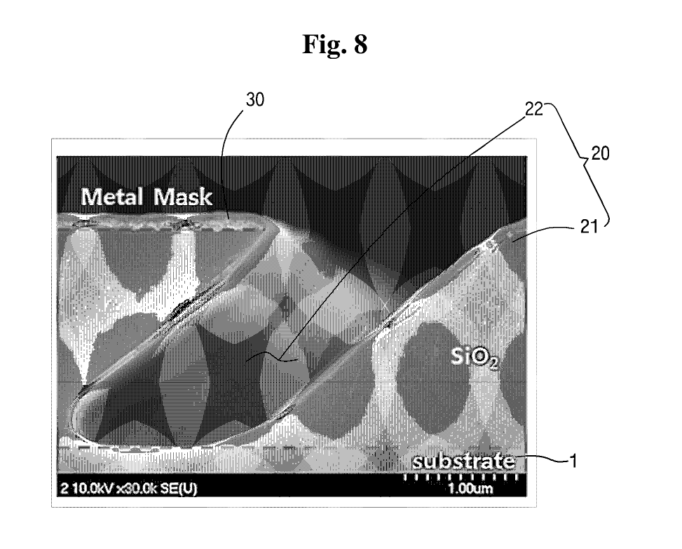

FIGS. 2a to 2d are sectional views of a mask for forming a semiconductor layer according to the present invention, and a method of fabricating the same. FIG. 8 is a scanning electron microscope image of the mask for forming a semiconductor layer according to the present invention.

First, referring to FIG. 2d and FIG. 8, the mask for forming a semiconductor layer 20 is placed on a growth surface of a substrate 1, which serves as a growth base. The mask includes at least one opening 22 formed between growth blocking portions 21, as shown in FIG. 2d. Each opening 22 partially exposes the growth surface of substrate 1 at a bottom thereof and is oblique with respect to the growth surface of substrate 1.

When a semiconductor layer is grown using the mask 20 including the at least one opening 22 oblique with respect to the surface of substrate 1, sidewalls of the opening 22 of the mask 20 can effectively block threading dislocation produced in a vertical direction in a growth process.

Now, a method of fabricating the mask for forming a semiconductor layer will be described in detail with reference to FIGS. 2a to 2d, and FIG. 8. Hereinafter, the mask for forming a semiconductor layer will be also referred to as a growth mask 20.

First, referring to FIG. 2a, a growth blocking layer 2 is formed on an upper surface of a substrate 1, i.e. a growth surface of the substrate 1. The substrate 1 may be, for example, a sapphire substrate, a silicon substrate, and the like. The growth blocking layer 2 formed on the growth surface of the substrate 1 may be a SiO₂ layer stacked by, for example, PECVD.

Referring to FIG. 2b, an etching mask 30 is formed on the growth blocking layer 2. The etching mask 30 may include a material having dry etching selectivity with respect to the growth blocking layer 2. By way of example, in this embodiment, the etching mask 30 may be formed by stacking a metal layer on the growth blocking layer 2, followed by patterning.

Referring to FIG. 2c, with the growth blocking layer 2 masked by the etching mask 30, the substrate 1 is tilted, followed by partially removing the growth blocking layer 2 by dry etching such as RIE (reactive ion etching) to form one or more openings 22. Each of the openings 22 is formed to expose the upper surface of the substrate 1, i.e. the growth surface of the substrate 1 at a bottom thereof. By forming the one or more openings 22 in the growth blocking layer 2, a growth mask 20 having blocking portions 21 and the openings 22 is formed. FIG. 2d shows a state in which the etching mask 30 is removed.

The one or more openings 22 of the growth mask 20, formed in this manner, become oblique with respect to the growth surface of the substrate 1.

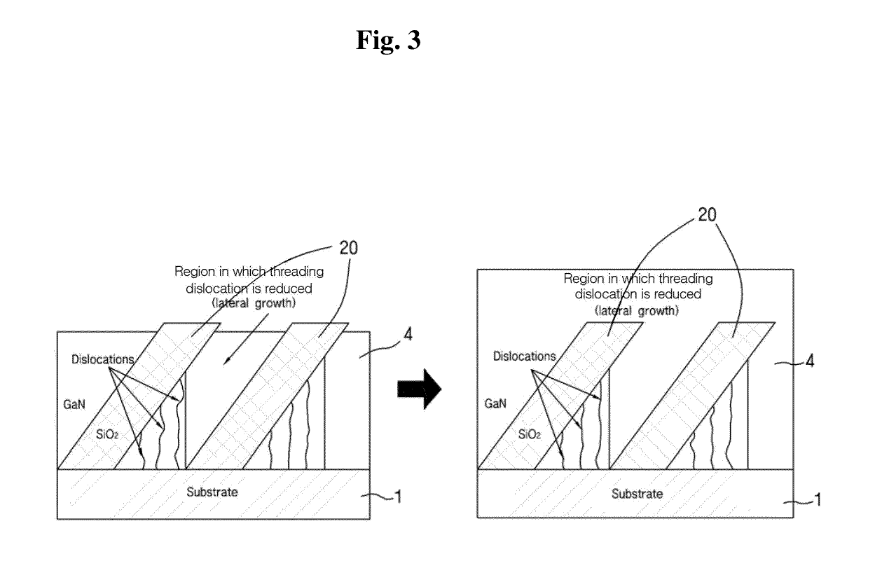

Referring to FIG. 3, when a semiconductor layer is formed on the substrate 1 using the growth mask 20 having one or more oblique openings 22, sidewalls of the openings 22 suppress longitudinal growth from the heterogeneous substrate 1, including threading dislocation, to a minimum and induce lateral growth, thereby reducing vertical threading dislocation in the semiconductor layer.

The one or more openings 22, as set forth above, may have a stripe or rod (column) shape. The stripe shape refers to a groove shape. A semiconductor layer grown through such a stripe or rod-shaped opening is grown corresponding to the shape of the openings.

The growth mask 20 or the mask for forming a semiconductor layer can be applied to manufacture of a semiconductor device in various ways.

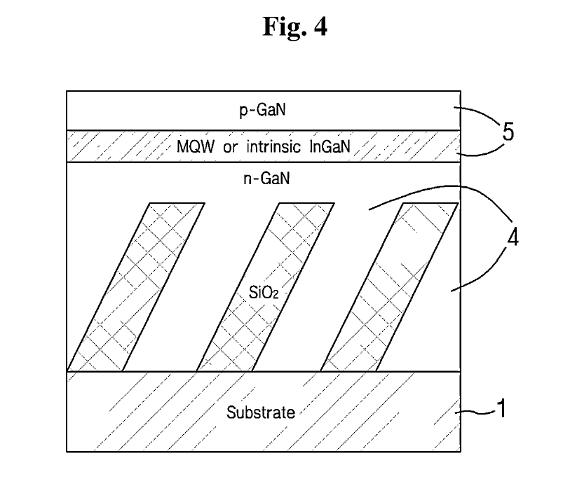

FIG. 4 is a view showing one example of a semiconductor device manufactured using the mask for forming a semiconductor layer according to the present invention.

Referring to FIG. 4, a first semiconductor layer 4 may be grown using the mask 20 and an upper structure layer 5 may be formed on the first semiconductor layer 4. As described above, in the first semiconductor layer 4, threading dislocation is restrictively produced within a portion which is placed directly on the substrate, and thus grown adjoining the substrate 21. In the example shown in FIG. 4, the first semiconductor layer 4 is sufficiently grown to cover an upper portion of the growth mask 20, followed by forming the upper structure layer 5 on the first semiconductor layer 4, thereby preparing the semiconductor device.

In the example in FIG. 4, the substrate 1 may be a sapphire substrate, a silicon substrate, or the like, and the growth mask 20 formed on the substrate may be formed of SiO₂. In this example, an LED is formed on the substrate 1. The grown first semiconductor layer 4 may be an n-GaN layer, and the upper structure layer 5 formed on the first semiconductor layer may include MQW (or intrinsic InGaN) and a p-GaN layer as a second semiconductor layer.

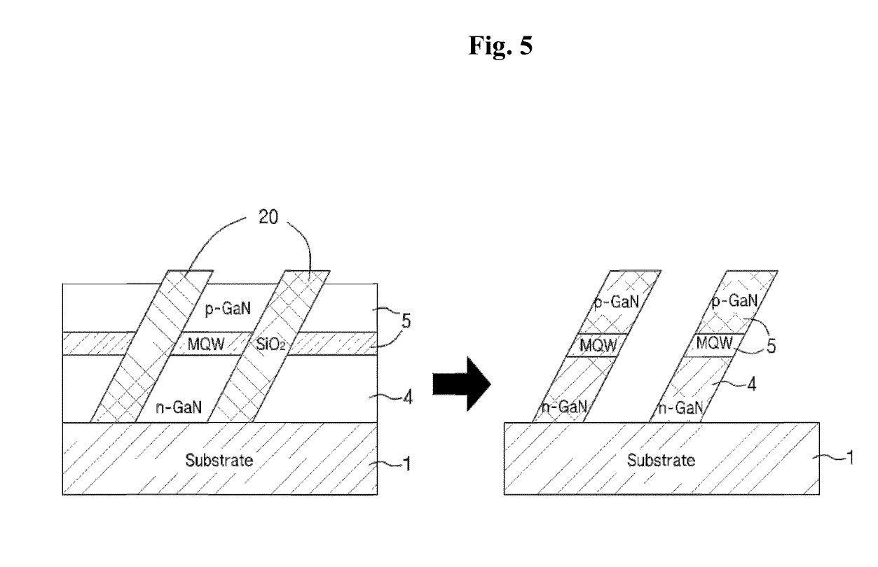

FIG. 5 is a view showing another example of a semiconductor device manufactured using the mask for forming a semiconductor layer according to the present invention.

In the example of FIG. 5, an n-GaN layer corresponding to the first semiconductor layer 4, and MQW/p-GaN corresponding to the upper structure layer 5 are grown within the openings 22 of the growth mask 20, followed by removing the growth mask 20.

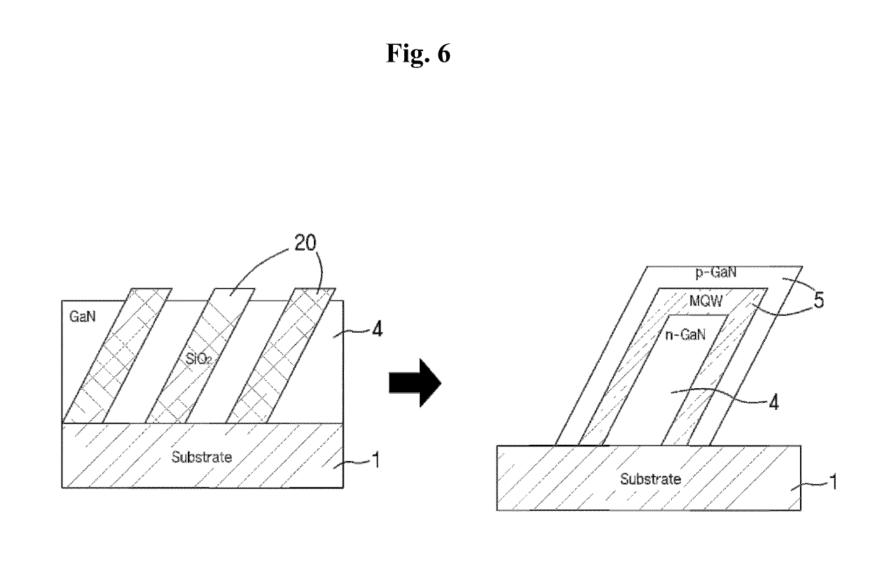

FIG. 6 is a view showing a further example of a semiconductor device manufactured using the mask for forming a semiconductor layer according to the present invention.

In the example of FIG. 6, an n-GaN layer corresponding to the first semiconductor layer 4 is formed within the openings 22 of the growth mask 20, and the growth mask 20 is removed, followed by forming a semiconductor device having a core-shell structure. By way of example, the upper structure layer 5 including MQW and p-GaN layers may be formed on an overall outer surface including an upper surface and side surfaces of the first semiconductor layer 4, thereby preparing a semiconductor device having a core-shell structure.

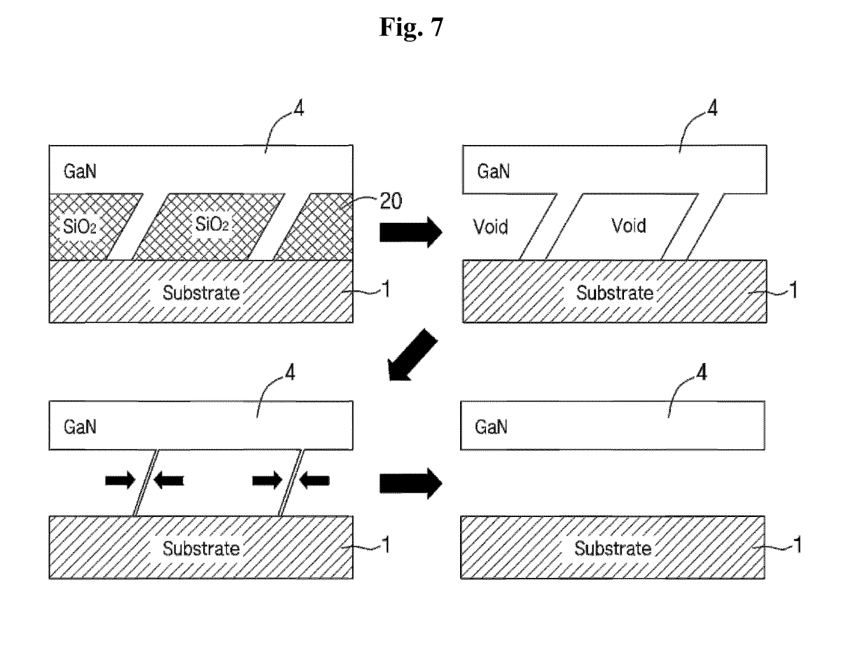

FIG. 7 is a view illustrating yet another example of a method of fabricating a semiconductor device using the mask for forming a semiconductor layer according to the present invention.

As shown in FIG. 7, in this example, the first semiconductor layer 4 is grown on the substrate 1 using the growth mask 20 as set forth above, followed by separating the substrate 1 from the first semiconductor layer 4.

By way of example, the growth mask 20 is formed on the substrate 1, followed by growing the first semiconductor layer 4 to merge into an upper surface of the growth mask 20. Then, SiO₂, which is the growth mask 20, is removed by wet etching. Next, a portion of GaN which has been located within the growth mask 20 is removed using an etchant such as KOH to separate the first semiconductor layer 4 from the substrate 1. As a result, there is an advantageous effect in that the semiconductor device is separated from the substrate while removing a portion in which threading dislocation is partially produced.

FIG. 8 is a scanning electron microscope image of the mask for forming a semiconductor layer according to the present invention. As can be seen in the micrograph, the growth mask 20 having the blocking portions 21 and the openings 22 was formed on the substrate 1 by tilting the substrate 1 and dry etching the growth blocking layer with the growth blocking layer masked by the etching mask 20. In particular, it can be ascertained that the openings 22 of the growth mask 20 were obliquely formed with respect to the upper surface (growth surface) of the substrate 1.

Although the present invention has been described with reference to some embodiments, it should be understood that the foregoing embodiments are provided for illustration only and are not to be construed in any way as limiting the present invention, and that various modifications, changes, alterations, and equivalent embodiments can be made by those skilled in the art without departing from the spirit and scope of the invention.

What is claimed is:

1. A semiconductor device comprising:
a first semiconductor layer formed on a substrate; and
an upper structure layer formed on the first semiconductor layer,
wherein at least the first semiconductor layer is partially or entirely oblique with respect to an upper surface of the substrate.

2. The semiconductor device according to claim 1, wherein the upper structure layer to comprises an MQW layer and a second semiconductor layer.

3. The semiconductor device according to claim 1, wherein the first semiconductor is grown on the upper surface of the substrate.

4. The semiconductor device according to claim 3, wherein the first semiconductor layer is masked by a growth mask formed on the upper surface of the substrate and having at least one opening exposing the upper surface of the substrate therethrough, while being grown in the opening.

5. The semiconductor device according to claim 4, wherein the first semiconductor layer is formed to cover an upper portion of the growth mask and enclose the growth mask.

6. The semiconductor device according to claim 2, wherein the MQW layer is formed to surround an upper surface and side surfaces of the first semiconductor layer.

7. The semiconductor device according to claim 6, wherein the second semiconductor layer is formed to surround an upper surface and side surfaces of the MQW layer.

8. A method of fabricating semiconductor devices, comprising:
(a) forming a growth mask including at least one opening oblique with respect to an upper surface of a substrate and formed to expose the upper surface of the substrate on the substrate therethrough; and
(b) forming a first semiconductor layer within the at least one opening.

9. The method according to claim 8, wherein forming a growth mask comprises:
(a1) forming a growth blocking layer having a predetermined thickness on the substrate;
(a2) forming an etching mask on an upper surface of the growth blocking layer; and
(a3) tilting the substrate and dry etching the growth blocking layer to expose the upper surface of the substrate, with the growth blocking layer masked by the etching mask.

10. The method according to claim 8, wherein forming a first semiconductor layer comprises:
growing the first semiconductor layer on the upper surface of the substrate exposed through the at least one opening.

11. The method according to claim 10, further comprising:
forming an upper structure layer including a second semiconductor layer on the first semiconductor layer within the at least one opening.

12. The method according to claim 10, further comprising:
removing the growth mask; and
forming an upper structure layer including a second semiconductor layer on an upper surface and side surfaces of the first semiconductor layer.

13. The method according to claim 10, wherein the first semiconductor layer is grown beyond the opening to cover an upper portion of the growth mask.

14. The method according to claim 13, further comprising:
selectively removing the growth mask; and
removing a portion of the first semiconductor layer located within the at least one opening to separate the first semiconductor layer from the substrate.
